(19) United States
(12) Patent Application Publication
(10) Pub. No.: US 2009/0295041 A1
(43) Pub. Date: Dec. 3, 2009

(54) PRINTING FORM PRECURSOR AND PROCESS FOR PREPARING A STAMP FROM THE PRECURSOR

(75) Inventors: MARIA PETRUCCI-SAMIJA, Newark, DE (US); Graciela Beatriz Blanchet, Boston, MA (US); Robert Blomquist, River Edge, NJ (US); Hee Hyun Lee, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I.DU PONT DE NEMOURS AND COMPANY, Wilmington, DE (US)

(21) Appl. No.: 12/533,506

(22) Filed: Jul. 31, 2009

Related U.S. Application Data
(62) Division of application No. 11/479,779, filed on Jun. 30, 2006.

(51) Int. Cl. B29C 35/08; G03F 7/004; G03F 7/20; B05D 5/00; B32B 3/00

(52) U.S. Cl. 264/494; 430/270.1; 430/320; 430/286.1; 427/256; 428/156

(57) ABSTRACT

The invention pertains to a printing form precursor and a method for preparing a stamp from the precursor for use in soft lithographic applications. The printing form precursor includes a composition layer of a fluorinated compound capable of polymerization upon exposure to actinic radiation and a flexible support transparent to the actinic radiation adjacent the composition layer.

### BACKGROUND OF THE INVENTION

1. Field of the Invention

This invention pertains to a printing form precursor, and a method for forming a stamp having a relief structure from the printing form precursor, and in particular, a printing form precursor for forming a stamp having a relief surface for use in microfabricating electronic components and devices.

2. Description of Related Art

Soft lithography shares a common feature of using a patterned elastomer block as a stamp, mold, or mask to generate micropatterns and microstructures. Soft lithography encompasses several techniques of using the elastomer block with a patterned relief structure to generate the micro patterns and structures, including microcontact printing (μCP), replica molding (REM), embossing, micro transfer molding (μTM), micromolding in capillaries (MIMIC), solvent-assisted micromolding (SAMIM), and phase-shift photolithography.

The stamp utilized in soft lithography is most often formed of an elastomeric material that is usually composed of polydimethylsiloxane (PDMS). PDMS denotes the reactive monomer, a reactive oligomer or a mixture thereof as well as filler and polymerization catalysts. In the current method of preparing stamps used in high precision soft lithography, liquid PDMS is introduced into a mold wherein a negative relief microcircuit pattern is expressed. The polymer is thereupon cured to produce a solidified stamp which is removed from the mold. The solidified stamp has a microcircuit pattern expressed in a positive relief. It is this pattern that is transferred to a substrate in subsequent steps in the soft lithographic printing processes.

Polydimethylsiloxane (PDMS) based networks offer several advantages for soft lithography techniques. For example, PDMS is highly transparent to ultraviolet radiation and has a very low Young's modulus which gives it the flexibility required for conformal contact even over surface irregularities, without the potential for cracking, Further, flexibility of a stamp facilitates the easy release of the stamp from a master and allows the stamp to endure multiple printing steps without damaging fragile features. However, several properties inherent to PDMS severely limit its capabilities. First PDMS based elastomers swell when exposed to most organic soluble compounds. Swelling resistance of the stamp is important in the majority of soft lithographic techniques because the fidelity of the features on the stamp need to be retained. Additionally, acidic or basic aqueous solution react with PDMS that can cause breakage of the polymer chain. Secondly, the surface energy of PDMS can not be easily controlled and can cause difficulties in printing procedures that require high fidelity. For this reason, the patterned surface of PDMS based molds may be fluorinated using a plasma treatment followed by vapor deposition of a fluoroalkyl trichlorosilane. These fluorine treated silicones still swell however when exposed to organic solvents. Third, the most commonly used commercially available form of the material used in PDMS molds, SYLGARD silicone elastomer base from Dow Chemicals, has a modulus that is too low for many applications. The low modulus of these commonly used PDMS materials results in sagging and bending of features and as such is not well suited for processes that require precise pattern placement and alignment.

Rigid materials, such as quartz glass and silicon, also have been used in imprint lithography. These materials are superior to PDMS in modulus and swelling resistance, but lack flexibility. Such lack of flexibility inhibits conformal contact with the substrate and causes defects in the mold and/or replicate during separation. Sometimes it may be necessary to use vacuum to assure adequate contact of the rigid mold to a substrate. Another drawback of rigid materials is the necessity to use a costly and difficult to fabricate hard mold, which is typically made by using conventional photolithography or electron beam (e-beam) lithography.

PCT Publication WO 2005/101466 A2 discloses the use of fluorinated elastomer-based materials, in particular perfluoropolyether (PFPE)-based materials, in high-resolution soft or imprint lithographic applications such as contact molding of organic materials to generate high fidelity features. Fluorinated elastomeric materials are solvent resistant since the material neither swells nor dissolves in common hydrocarbon-based organic solvents or acidic or basic aqueous solutions. PFPE materials have a low surface energy, are non-toxic, UV transparent, highly gas permeable, and cure into an elastomer which easily releases from a master mold. A patterned template is formed from elastomer-based materials by casting low viscosity liquid material onto a master template and then curing the liquid material. The properties of the elastomer-based molding materials can be adjusted by adjusting the composition of the ingredients used to make the materials. Modulus can be adjusted from low (approximately 1 Mpa) to multiple Gpa. These patterned templates or stamps are freestanding, that is, the elastomeric layer alone forms the stamp.

Freestanding stamps made of PFPE can have a problem with dimensional instability; that is, elastomeric layer can deform or warp during formation and during use. Additionally, the freestanding stamp can have a surface roughness that precludes the stamp for use in printing of high-resolution patterns. Further, it is difficult to form relatively large dimension (on the order of 12 by 12 in) freestanding stamps having uniform thickness of the elastomeric material.

U.S. Pat. No. 6,656,308 B2 discloses a process of fabricating a microcontact printing stamp. In the process an elastomeric microcontact printing stamp is formed by curing an elastomeric monomer or oligomer in a mold having a photoresist master defining a microcircuit pattern. The mold includes opposite the photoresist master a flexible backing assembly composed of a flexible backplane and a flat and rigid planar member sheet laminated to the flexible backplane. An adhesive is disposed between the flexible backplane and the planar member sheet. The backplane is a flexible metal. The elastomeric monomer or oligomer is cured thermally to produce a thermoset elastomeric stamp. After curing, the flat and rigid planar member is delaminated from the flexible backplane of the stamp by either exposure to ultraviolet light or laser light. The flexible backplane remains with the microcontact stamp.

For U.S. Pat. No. 6,656,308 B2 the flat and rigid planar member prevents undulations of the flexible backplane arising from shrinkage of the thermal curing elastomeric layer, since the flexible backplane alone is not sufficient to prevent undulation problems. This process of fabricating the stamp is rather cumbersome and time-consuming as it presents additional steps of laminating the flexible backplane to the rigid planar member, and after thermal curing the elastomer, delaminating the flexible backplane from the rigid planar member.

Thus there is a need in the art for a printing form precursor that is dimensionally stable and can be used in various soft lithographic techniques requiring high resolution patterns, particularly patterns having features on the order of 10 microns or less. The printing form precursor should be capable of forming a relief structure that can create fine pitch electronic patterns suitable for use in microelectronic devices and components. Further there is a need of a simplified process of forming a stamp from the printing form precursor.

### SUMMARY OF THE INVENTION

In accordance with this invention there is provided a printing form precursor for forming a relief structure. The printing form precursor comprises a layer of a composition comprising a fluorinated compound capable of polymerization by exposure to actinic radiation; and a support of a flexible film transparent to the actinic radiation adjacent the layer.

In accordance with another aspect of this invention there is provided a method for making a stamp from the printing form precursor. The method comprises (a) providing the printing form precursor onto a master having a relief pattern such that the composition layer contacts the relief pattern; (b) exposing the layer through the support to the actinic radiation, to polymerize the layer; and (c) separating the polymerized layer from the master to form the stamp having a relief surface corresponding to the relief pattern of the master.

### BRIEF DESCRIPTION OF THE DRAWINGS

FIG. 1 is a sectional elevation view of a master having a pattern in relief of a microcircuit or other electronic pathway.

FIG. 2 is a sectional elevation view of one embodiment of a support having a layer of an adhesive.

FIG. 3 is a sectional elevation view of one embodiment of a printing form precursor having a layer of a fluorinated elastomer (PFPE) between the support and the master.

FIG. 4 is a sectional elevation view of the printing form precursor of FIG. 3 where the layer of elastomer is being exposed to actinic radiation to cure.

FIG. 5 is a sectional elevation view of a stamp formed of the printing form precursor separating from the master. The stamp has a relief surface corresponding to the relief pattern of the master, and in particular, the stamp surface is a relief pattern that is negative or opposite the relief pattern of the master.

### DESCRIPTION OF THE PREFERRED EMBODIMENTS

Throughout the following detailed description, similar reference characters refer to similar elements in all figures of the drawings.

The present invention describes a printing form precursor and a process of making a stamp from the printing form precursor. The stamp is suitable for use in soft lithographic techniques, including but not limited to microcontact printing, imprinting (embossing), replica molding, microtransfer molding, and micromolding. The stamp includes a relief structure that is particularly suited for printing of electronic patterns in the fabrication of electronic components and devices, and more particularly for printing microcircuitry. The printing form precursor includes a layer of a composition containing a fluorinated compound that reacts to actinic radiation and a support of a flexible film that is transparent to the actinic radiation and adjacent the photosensitive layer. The composition containing a fluorinated compound may also be called a photosensitive composition. The fluorinated compound may be elastomeric or may become elastomeric upon exposure to the actinic radiation. The support provides dimensional stability to the stamp such that the elastomeric layer does not distort or warp during preparation. The support also helps to maintain the integrity of the relief structure of the stamp throughout soft lithographic end-use processes. In particular, the stamp having the support is dimensionally stable such that the elastomeric relief structure can print patterns on a micron scale, that is, 1-10 microns, or less. Stamps made from the printing form precursor of the present invention also have a printing relief surface that is sufficiently smooth to assure high resolution of the micron-scale electronic patterns being printed. The presence of the support in the stamp also aids in handling of the stamp during soft lithographic operations. In addition, the presence of the support in the stamp can increase the longevity of the stamp during printing. The stamp may also be referred to herein as a template, or plate, or printing plate, or printing form.

Unless otherwise indicated, the following terms as used herein have the meaning as defined below.

“Actinic radiation” refers to radiation capable of initiating reaction or reactions to change the physical or chemical characteristics of a photosensitive composition.

“Visible radiation or light” refers to wavelengths of radiation between about 390 and 770 nm.

“Ultraviolet radiation or light” refers to wavelengths of radiation between about 10 and about 390 nm.

Note that the provided ranges of wavelengths for visible and ultraviolet are general guides and that there may be some overlap of radiation wavelengths between what is generally considered ultraviolet radiation and visible radiation.

The printing form precursor includes a layer of a composition sensitive to actinic radiation, that is, the composition is photosensitive. The term “photosensitive” encompasses any system in which the photosensitive composition is capable of initiating a reaction or reactions, particularly photochemical reactions, upon response to actinic radiation. Upon exposure to actinic radiation, chain propagated polymerization of a monomer and/or oligomer is induced by either a condensation mechanism or by free radical addition polymerization. While all photopolymerizable mechanisms are contemplated, the compositions and processes of this invention will be described in the context of free-radical initiated addition polymerization of monomers and/or oligomers having one or more terminal ethylenically unsaturated groups. In this context, the photoinitiator system when exposed to actinic radiation can act as a source of free radicals needed to initiate polymerization of the monomer and/or oligomer.

The composition is photosensitive since the composition contains a fluorinated compound having at least one ethylenically unsaturated group capable of forming a polymer by photoinitiated addition polymerization. The photosensitive composition may also contain an initiating system activated by actinic radiation to induce photopolymerization. The fluorinated compound may have non-terminal ethylenically unsaturated groups, and/or the composition may contain one or more other components, such as a monomer, that promote crosslinking. As such, the term “photopolymerizable” is intended to encompass systems that are photopolymerizable, photocrosslinkable, or both. As used herein, photopolymerization may also be referred to as curing.

The photosensitive composition includes a fluorinated compound that polymerizes upon exposure to actinic radiation. The fluorinated compound may be elastomeric or may become elastomeric upon exposure to the actinic radiation, and thus forms a fluorinated elastomeric-based material. The layer of fluorinated elastomeric-based material of the stamp may also be referred to as a fluorinated elastomeric layer, cured layer, or cured elastomeric layer, or elastomeric layer. Suitable elastomeric-based fluorinated compounds include, but are not limited to, perfluoropolyethers, fluoroolefins, fluorinated thermoplastic elastomers, fluorinated epoxy resins, fluorinated monomers and fluorinated oligomers that can be polymerized or crosslinked by a polymerization reaction. In one embodiment, the fluorinated compound has one or more terminal ethylenically unsaturated groups that react to polymerize and form the fluorinated elastomeric material. The elastomeric-based fluorinated compounds can be homopolymerized or copolymerized with polymers such as polyurethanes, polyacrylates, polyesters, polysiloxanes, polyamides, and others, to attain desired characteristics of the printing form precursor and/or the stamp suitable for its use. Exposure to the actinic radiation is sufficient to polymerize the fluorinated compound and render its use as a sprinting stamp, such that application of high pressure and/or elevated temperatures above room temperature is not necessary. An advantage of compositions containing fluorinated compounds that cure by exposure to actinic radiation is that the composition cures relatively quickly (e.g., in a minutes or less) and has a simple process development, particularly when compared to compositions that thermally cure such as PDMS based systems. Another advantage of compositions containing the elastomeric-based fluorinated compound is that the compositions are solventless and thus there are no VOC (volatile organic compounds) concerns with its use.

In one embodiment, the printing form precursor includes a layer of the photosensitive composition wherein the fluorinated compound is a perfluoropolyether (PFPE) compound. A perfluoropolyether compound is a compound that includes at least a primary proportion of perfluoroether segments, i.e., perfluoropolyether. The primary proportion of perfluoroether segments present in the PFPE compound is equal to or greater than 80 weight percent, based on the total weight of the PFPE compound. The perfluoropolyether compound may also include one or more extending segments that are hydrocarbons or hydrocarbon ethers that are not fluorinated; and/or, are hydrocarbons or hydrocarbon ethers that may be fluorinated but are not perfluorinated. In one embodiment, the perfluoropolyether compound includes at least the primary proportion of perfluoropolyether segments and terminal photoreactive segments, and optionally extending segments of hydrocarbon that are not fluorinated. The perfluoropolyether compound is functionalized with one or more terminal ethylenically unsaturated groups that render the compound reactive to the actinic radiation (i.e., photoreactive segments). The photoreactive segments may also be referred to as photopolymerizable segments.

The perfluoropolyether compound is not limited, and includes linear and branched structures, with linear backbone structures of the perfluoropolyether compound being preferred. The PFPE compound may be monomeric, but typically is oligomeric and a liquid at room temperature. The perfluoropolyether compound may be considered an oligomeric difunctional monomer having oligomeric perfluoroether segments. Perfluoropolyether compounds photochemically polymerize to yield the elastomeric layer of the stamp. An advantage of the PFPE based materials is that PFPEs are highly fluorinated and resist swelling by organic solvents, such as methylene chloride, chloroform, tetrahydrofuran, toluene, hexanes, and acetonitrile among others, which are desirable for use in soft lithographic techniques. PFPE based materials also are hydrophobic, typically exhibiting water contact angles greater than 90 degrees.

In this embodiment, the molecular weight of the PFPE compound is not particularly limited. However PFPE compounds having a molecular weight less than about 4000 form a composition having low haze which can cure more effectively and completely. In one embodiment, the composition contains a mixture of PFPE compounds having a range of molecular weights wherein the number average molecular weight is between about 250 to about 4000. Unless otherwise indicated, the molecular weight of the fluorinated compound, i.e., PFPE compound, is a number average molecular weight as determined by GC-MS for molecular weights less than about 1000 and gel permeation chromatography (GPC) for molecular weights greater than about 1000.

The preparation of perfluoropolyether compounds functionalized with photoreactive groups for polymerizing is well-known in the art. Suitable methods of preparing perfluoropolyether compounds with photoreactive groups are described for example in U.S. Pat. Nos. 3,810,874 and 3,849,504.

In one embodiment, the photosensitive composition includes as the fluorinated compound, a perfluoropolyether compound of Formula 1:

R-E-CF₂—O—(CF₂—O—)ₙ(—CF₂—CF₂—O—)ₘ—CF₂-E′-R′ Formula 1

wherein n and m designate the number of randomly distributed perfluoromethyleneoxy (CF₂O) and perfluoroethyleneoxy (CF₂CF₂O) backbone repeating subunits, respectively and wherein a ratio of m/n can be from 0.2/1 to 5/1; E and E′, which can be the same or different, are each an extending segment selected from the group consisting of linear alkyls of 1 to 10 carbon atoms, branched alkyls of 1 to 10 carbon atoms, linear hydrocarbon ethers of 1 to 10 carbon atoms, and branched hydrocarbon ethers of 1 to 10 carbon atoms; and, R and R′, which can be the same or different, are photoreactive segments selected from the group consisting of acrylates, methacrylates, allylics, and vinyl ethers. Preferred for the photoreactive segments, R and R′, are acrylates and methacrylates. The photoreactive segments are photopolymerizable segments that will undergo free-radical reaction upon exposure to actinic radiation to form the polymerized elastomeric product. The extending segments of hydrocarbon ethers can have one or more ether oxygen atoms that can be internal and/or terminal to the segment. Each of the extending segments, E and E′, of alkyls and hydrocarbon ethers can be non-fluorinated, or can be fluorinated, but not perfluorinated. In one embodiment, the extending segments, E and E′, are non-fluorinated hydrocarbon ethers of 1 to 10 carbon atoms.

In one embodiment of the PFPE compound of Formula 1, n and m designate the number of randomly distributed perfluoromethyleneoxy and perfluoroethyleneoxy backbone repeating subunits that provide the compound of Formula 1 with a molecular weight of about 250 to about 4000. In another embodiment, the PFPE compound of Formula 1 has an average molecular weight of about 250 to about 4000. In one embodiment of the PFPE compound of Formula 1, the extending segments E and E′, which can be the same or different, are selected from the group consisting of linear alkyls having 1 to 4 carbon atoms, and branched alkyls having 1 to 4 carbon atoms. In another embodiment of the PFPE compound of Formula 1, the extending segments E and E′, which can be the same or different, are selected from the group consisting of linear hydrocarbon ethers having 1 to 4 carbon atoms, and branched hydrocarbon ethers having 1 to 4 carbon atoms.

In one preferred embodiment, the photosensitive composition includes as the fluorinated compound, a perfluoropolyether compound of Formula 1A.

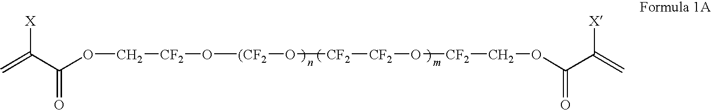

wherein n and m designate the number of randomly distributed perfluoromethyleneoxy (CF₂O) and perfluoroethyleneoxy (CF₂CF₂O) backbone repeating subunits, respectively, and wherein a ratio of m/n can be from 0.2/1 to 5/1, and X and X′ which can be the same or different, are selected from the group consisting of hydrogen and methyl.

One suitable method of preparing the perfluoropolyether compounds of Formula 1A is by reacting perfluoropolyether-diols with acryloyl chloride.

In one embodiment of the PFPE compound of Formula 1A, n and m designate the number of randomly distributed perfluoromethyleneoxy and perfluoroethyleneoxy backbone repeating subunits that provide the compound of Formula 1A with a molecular weight of about 250 to about 4000. In another embodiment, the PFPE compound of Formula 1A has an average molecular weight of about 250 to about 4000. In one embodiment, the molecular weight of the PFPE compound of Formula 1A is between about 250 and about 3800. In another embodiment, the molecular weight of the PFPE compound of Formula 1A is between about 900 and about 3000. In another embodiment the molecular weight of the PFPE compound of Formula 1A is between about 900 and about 2100.

Stamps forming an elastomeric layer of the PFPE compound (including the PFPE compounds of Formulas 1 and 1A) that have a molecular weight less than about 4000, and in particular less than about 2000, have a modulus of elasticity of at least 10 mega Pascals. Stamps having an elastomeric layer where the modulus of elasticity is above 10 mega Pascals, preferably above 20 mega Pascals, and most preferably above 35 mega Pascals, are capable of printing a low ratio of feature to space patterns (determined by width of features divided by width between the features), as well as high aspect ratio of features (determined by width of features divided by height of the features on the stamp) for electronic devices and components.

The cured elastomeric layer of the stamp having elastic modulus greater than 10 mega Pascals exhibits less sagging that aids in the printing process. Sagging of the relief surface of the stamp is a phenomenon in which a lowermost surface of recessed areas of the relief surface collapse or sag toward an uppermost surface of the raised areas of the relief surface. Sagging may also be called roof collapse of the stamp. Sagging of the relief surface causes the recessed areas to print where there should be no image.

In one embodiment, the photosensitive composition may be composed of one or a mixture of the fluorinated elastomeric-based compounds having one or more polymerization functional groups that will undergo free-radical reaction to form a polymeric elastomeric product. In another embodiment, the photosensitive composition may be composed of one or a mixture of the PFPE compounds having one or more polymerization functional groups that will undergo free-radical reaction to form a polymeric elastomeric product. In another embodiment, the photosensitive composition may be composed of one or a mixture of the PFPE compounds according to Formula 1 to form a polymeric elastomeric product. In another embodiment, the photosensitive composition may be composed of one or a mixture of the PFPE compounds according to Formula 1A to form a polymeric elastomeric product.

In an alternate embodiment, the photosensitive composition may include one or more constituents and/or additives with the fluorinated elastomeric-based compound. The one or more constituents may be present in the photosensitive composition provided that they are compatible with the fluorinated elastomeric-based compound to the extent that a clear or substantially clear (non-cloudy or non-hazy) layer of the photosensitive composition is produced. By compatibility is meant the ability of two or more constituents to remain dispersed or miscible with one another without causing appreciable scattering of actinic radiation. Typically this is accomplished when the constituent or constituents are soluble in the fluorinated compound. Compatibility is often limited by the relative proportions of the constituents and incompatibility is evidenced by formation of haze in the photosensitive composition. Some light haze of a layer formed from such compositions before or during exposure can be tolerated in the preparation of printing forms, but haze is preferably avoided. Photosensitive compositions having low or no haze cure, that is photopolymerize, more effectively and completely. The amount of constituent used is therefore limited to those compatible concentrations below that which produced undesired light scatter or haze.

In one embodiment, the photosensitive composition includes a photoinitiator with the fluorinated elastomeric-based compound. In another embodiment, the photosensitive composition includes a photoinitiator and one or more ethylenically unsaturated compounds with the fluorinated elastomeric-based compound.

The photoinitiator can be any single compound or combination of compounds which is sensitive to actinic radiation, generating free radicals which initiate the polymerization without excessive termination. Any of the known classes of photoinitiators, particularly free radical photoinitiators such as aromatic ketones, quinones, benzophenones, benzoin ethers, aryl ketones, peroxides, biimidazoles, benzyl dimethyl ketal, hydroxyl alkyl phenyl acetophone, dialkoxy actophenone, trimethylbenzoyl phosphine oxide derivatives, aminoketones, benzoyl cyclohexanol, methyl thio phenyl morpholino ketones, morpholino phenyl amino ketones, alpha halogennoacetophenones, oxysulfonyl ketones, sulfonyl ketones, oxysulfonyl ketones, sulfonyl ketones, benzoyl oxime esters, thioxanthrones, camphorquinones, ketocouumarins, Michler's ketone may be used. Alternatively, the photoinitiator may be a mixture of compounds, one of which provides the free radicals when caused to do so by a sensitizer activated by radiation. Liquid photoinitiators are particularly suitable since they disperse well in the composition. Preferably, the initiator is sensitive to ultraviolet radiation. Photoinitiators are generally present in amounts from 0.001% to 10.0% based on the weight of the photosensitive composition. In one embodiment, the photoinitiator is present in amounts from 0.5 to 5%, by weight, based on the weight of the photosensitive composition.

The photoinitiator can include a fluorinated photoinitiator that is based on known fluorine-free photoinitiators of the aromatic ketone type. The fluorinated photoinitiator is one in which a fluorine-containing moiety having a terminal fluoroalkyl group is attached to the photoinitiator by reacting functional group(s) in the fluorinated molecule with functional group(s) of the photoinitiator or its precursor in such a way that the connection will not significantly depress the photon-absorption and radical-formation characteristics. Examples of suitable fluorinated photoinitiators are disclosed by Wu in U.S. Pat. No. 5,391,587 and U.S. Pat. RE 35,060. In one embodiment, the fluorinated photoinitiator is a fluorinated aromatic ketone. An advantage of using fluorinated photoinitiators is that fluorinated photoinitiators are typically highly compatible with the fluorinated elastomeric-based compound and typically produce a clear, non-cloudy layer of the photosensitive composition.

The composition may include one or more an ethylenically unsaturated compounds capable of photoinitiated addition polymerization, which may also be referred to as a monomer. Typically the at least one ethylenically unsaturated compound is nongaseous and has a boiling point above 100° C. at normal atmospheric pressure. The ethylenically unsaturated compound is non-fluorinated. The composition may contain monofunctional or polyfunctional acrylates, and/or monofunctional or polyfunctional methacrylates. In one embodiment are compositions containing monomers with two, three or more acrylate or methacrylate groups to allow concurrent crosslinking during the photopolymerization process.

Monomers that can be used in the composition activated by actinic radiation are well known in the art, and include, but are not limited to, addition-polymerization ethylenically unsaturated compounds. The addition polymerization compound may also be an oligomer, and can be a single or a mixture of oligomers. The composition can contain a single monomer or a combination of monomers. The monomer compound capable of addition polymerization can be present in an amount less than 5%, preferably less than 3%, by weight of the composition.

Suitable monomers include, but are not limited to, acrylate monoesters of alcohols and polyols; acrylate polyesters of alcohols and polyols; methacrylate monoesters of alcohols and polyols; and methacrylate polyesters of alcohols and polyols; where the suitable alcohols and the polyols include alkanols, alkylene glycols, trimethylol propane, ethoxylated trimethylol propane, pentaerythritol, and polyacrylol oligomers. Other suitable monomers include acrylate derivatives and methacrylate derivatives of isocyanates, esters, epoxides, and the like. A combination of monofunctional and multifunctional acrylates or methacrylates may be used.

The composition may optionally contain at least one surfactant to improve dispersibility of the photoinitiator with the fluorinated elastomeric-based compound in order to form a haze-free dispersion. The surfactant may also aid in the spreading or coating of the photosensitive composition on the master to form the layer of the printing form precursor. The surfactant is not particularly limited provided that the surfactant is miscible in the photosensitive composition. In general, the surfactant is not limited and can include nonionic and ionic (anionic, cationic, and amphoteric) surfactants. In one embodiment, the surfactant includes one or more fluorinated moieties. Zonyl® product types PM4700 and FC3573 (from DuPont, Wilmington, Del.) are examples of fluorinated materials suitable for use in the photosensitive composition as the monomer that also contain a surfactant. The surfactant can be present in an amount of about 0.001 to 1%, by weight of the composition.

The photosensitive composition may contain other constituents such as thermal polymerization inhibitors, processing aids, antioxidants, photosensitizers, and the like to stabilize or otherwise enhance the composition.

The support is a flexible film, and preferably a flexible polymeric film. The flexible support is capable of conforming or substantially conforming the elastomeric relief surface of the stamp to a printable electronic substrate, without warping or distortion. The support is also sufficiently flexible to be able to bend with the elastomeric layer of the stamp while peeling the stamp from the master. The support can be almost any polymeric material that forms a film that is non-reactive and remains stable throughout conditions for making and using the stamp. Examples of suitable film supports include cellulosic films such as triacetyl cellulose; and thermoplastic materials such as polyolefins, polycarbonates, polyimides, and polyester. Preferred are films of polyethylene, such as polyethylene terephthalate and polyethylene napthalate. Also encompassed within a support is a flexible glass. Typically the support has a thickness between 2 to 50 mils (0.0051 to 0.13 cm). In one embodiment, the flexible film is 4 to 15 mils (0.010 to 0.038 cm). Typically the support is in sheet form, but is not limited to this form. The support is transparent or substantially transparent to the actinic radiation at which the photosensitive composition polymerizes. The support stabilizes and minimizes distortion of the cured layer of fluorinated elastomeric-based composition during the process to form the stamp from the printing form precursor and during the process of printing. The stabilizing effect of the support becomes apparent when the molecular weight of the fluorinated compound is less than about 4000, and in particular at molecular weights less than about 2000. The presence of the support in the printing stamp can also provide increased life of the stamp, allowing for increased number of stamp impressions. Additionally in some end-use applications, the transparency of the support for the stamp is necessary so that a material being printed by the stamp can be cured. For example, the stamp may be exposed through the transparent support to cure an electronic ink being printed by the stamp. The term electronic in this context for electronic inks is not limited, and can include, for example, conductive, semi-conductive, dielectric materials, etc.

A surface of the support can include an adhesion-promoting surface, such as a primer layer, or can be treated to promote adhesion of an adhesive layer to the support. The surface of the about support can include a subbing layer of an adhesive material or primer or an anchor layer to give strong adherence between the support and the adhesion layer or the support and the photosensitive composition. The subbing compositions that are disclosed in U.S. Pat. No. 2,760,863 and U.S. Pat. No. 3,036,913 are suitable. The surface of the support can be treated to promote adhesion between the support and the adhesive layer (or the photosensitive composition) with flame-treatment, mild acid, or electron-treatment, e.g., corona-treated.

Provided that the support retains its transparency and flexibility, one side of the support may also include a thin layer of metal. Preferably the thin layer of metal is adjacent and in contact with the layer of the fluorinated elastomeric-based composition. The thin layer of metal may provide the stamp with different surface energies between recessed portions of the relief surface and the raised portions of the relief surface, and thereby improve printing capability of the stamp. This is particularly the case if residual layer (i.e., floor) of elastomeric material in recessed portions can be removed by plasma treatment. Examples of metals suitable for use as the optional metal layer on the support and suggested thickness of the metal layer are as follows.

| Metal | Range of Thickness |
|---|---|
| ITO (Indium Tin Oxide) | 10 to 2000 Angstrom (1 to 200 nm) |
| SiOx (Silicon Oxide) | 10 to 2000 Angstrom (1 to 200 nm) |
| Al (Aluminum) | 10 to 200 Angstrom (1 to 20 nm) |
| Cr (Chromium) | 10 to 200 Angstrom (1 to 20 nm) |
| Ti (Titanium) | 10 to 200 Angstrom (1 to 20 nm) |
| Cu (Copper) | 10 to 200 Angstrom (1 to 20 nm) |

One side of the support may also include a layer of an adhesive. The adhesive layer can be on the adhesion-promoting surface, or on the primer layer of the support, or directly the surface of the support. The adhesive layer covers all or substantially all the surface of the support. The adhesive is not limited provided that the adhesive is optically transparent to the actinic radiation at which the fluorinated elastomeric-based composition is polymerized. Adhesives suitable for use can be found in “Handbook of Adhesives”, edited by 1. Skeist, Third Edition, Van Nostrand Reinhold Company, New York, 1990, particularly Chapter 38. Examples of suitable adhesives include, but are not limited to, natural rubber; butyl rubber; styrenic block copolymers, such as styrene-isoprene-styrene block copolymers and styrene-butadiene block copolymers; styrene-butadiene rubbers; homopolymers of isobutylene; ethylene-vinyl acetate copolymers; acrylics, such as poly(acrylate esters), and acrylic latexes; silicones; polyurethanes, and combinations thereof. In one embodiment, the adhesive is an adhesive that is activated, that is bonds and cures, by exposure to ultraviolet radiation. In one embodiment, the adhesive is a polyurethane acrylate. In another embodiment, the adhesive can be a polyfluoropolyether compound, such as the PFPE compounds represented by Formulas 1 and 1A, that have a molecular weight between about 240 and 600. In this case, the stamp formed from the printing form precursor would be multilayer, that is have two layers of fluorinated elastomeric-based materials. The adhesive may also include additives to adjust the adhesive or other properties of the layer or to aid in the application of the adhesive to form a layer on the support. The thickness of the adhesive layer is not limited. In one embodiment, the thickness of the adhesive layer can be between 1 to 5 micrometers (microns). In another embodiment, the thickness of the adhesive layer can less than 1 micron.

### Process of Preparing the Stamp

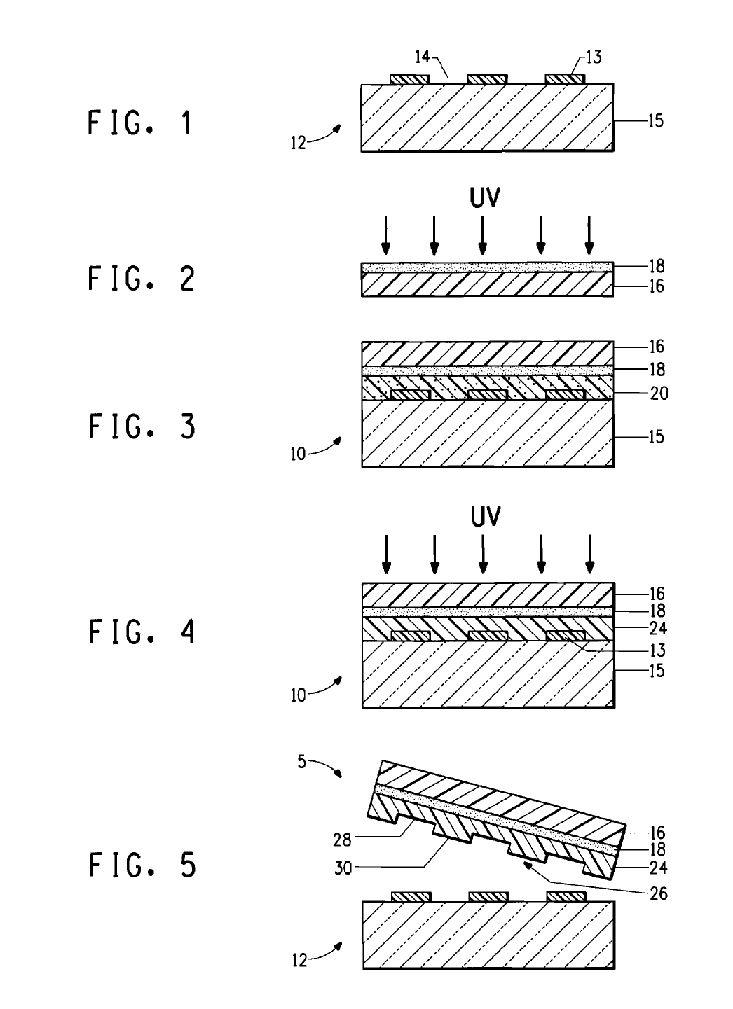

Referring to FIGS. 1 through 5, the method of preparing a stamp 5 from a printing form precursor 10 occurs in a molding operation. FIG. 1 depicts a master 12 having a pattern 13 of a negative relief of the microelectronic features formed on a surface 14 of a (master) substrate 15. The substrate 15 can be any smooth or substantially smooth metal, plastic, ceramic or glass. In one embodiment the master substrate is a glass or silicon plane. Typically the relief pattern 13 on the substrate 15 is formed of a photoresist material, according to conventional methods that are well within the skill in the art. Plastic grating films and quartz grating films can also be used as masters. If very fine features on the order of nanometers are desired, masters can be formed on silicon wafers with e-beam radiation.

The master 12 may be placed in a mold housing and/or with spacers (not shown) along its perimeter to assist in the formation of a uniform layer of the photosensitive composition. The process of the present invention can be simplified by forming the stamp without the presence of the mold housing or spacers.

In one embodiment as shown in FIG. 2, the support 16 for the printing form precursor 10 is prepared by applying a layer of the adhesive 18 to the support 16, and curing the adhesive by exposure to actinic radiation, for example, ultraviolet radiation. Application of the adhesive layer 18 can be accomplished by any method suitable to provide the desired thickness and uniformity. In another embodiment (not shown) the support includes a primer layer or is treated to promote adhesion of the photosensitive composition to the support.

As shown in FIG. 3, the photosensitive composition 20 is introduced to form a layer onto the surface of the master 12 having the relief pattern 13. The photosensitive composition can be introduced on to the master 12 by any suitable method, including but not limited to, injection, pouring, liquid casting and coating. Examples of suitable methods of coating include spin coating, dip coating, slot coating, roller coating, doctor blading. In one embodiment, the photosensitive composition is formed into a layer 20 by pouring the liquid onto the master. A layer of the photosensitive composition 20 is formed on the master such that after exposure to actinic radiation, the cured composition forms a solid elastomeric layer having a thickness of about 5 to 50 micron. In one embodiment, the cured elastomeric layer of fluorinated composition has a thickness between about 10 to 30 micron.

The support 16 is positioned on a side of the photosensitive composition layer 20 opposite the master 12 such that the adhesive layer 18 if present, is adjacent, and preferably contacts, the layer of the photosensitive composition, to form the printing form precursor 10. In one embodiment, the support 16 can be placed on the composition layer 20 manually with a slight amount of pressure to assure adequate contact of the support to the layer. The support 16 can be applied to the composition layer in any manner suitable to attain the printing form precursor 10. In one embodiment, a flat glass plate can be positioned on top of the support 16 to form even thickness of the photosensitive composition layer 20. Optionally, the glass plate may be present during the exposure to cure the layer 20, and if so, the precursor would be exposed through the glass plate. In embodiments in which the composition is composed of a PFPE compound having a molecular weight less than 4000, the composition will typically have low viscosity that helps to minimize air entrapment between the support 16 and the composition layer 20.

As shown in FIG. 4, upon exposure to actinic radiation through the transparent support 16 of the printing form precursor 10, the photosensitive layer 20 polymerizes and forms an elastomeric layer 24 of the fluorinated composition for the stamp 5. The layer of the photosensitive composition 20 cures or polymerizes by exposure to actinic radiation. Typically no additional pressure is necessary to polymerize the composition to its elastomeric state. Further, typically the exposure is conducted in a nitrogen atmosphere, to eliminate or minimize the presence of atmospheric oxygen during exposure and the effect that oxygen may have on the polymerization reaction.

The printing form precursor is exposed to actinic radiation, such as an ultraviolet (UV) or visible light. The actinic radiation enters the photosensitive material through the transparent support. The exposed material polymerizes and/or crosslinks and becomes a stamp or plate having a solid elastomeric layer with a relief surface corresponding to the relief pattern on the master. In one embodiment, suitable exposure energy is between about 10 and 20 Joules on a 365 nm I-liner exposure unit.

Actinic radiation sources encompass the ultraviolet, visible, and infrared wavelength regions. The suitability of a particular actinic radiation source is governed by the photosensitivity of the photosensitive composition, and in particular the fluorinated elastomeric-based compound and the optional initiator and/or the at least one monomer used in preparing the printing form precursor. The preferred photosensitivity of printing form precursor is in the UV and deep visible area of the spectrum, as they afford better room-light stability. Examples of suitable visible and UV sources include carbon arcs, mercury-vapor arcs, fluorescent lamps, electron flash units, electron beam units, lasers, and photographic flood lamps. The most suitable sources of UV radiation are the mercury vapor lamps, particularly the sun lamps. These radiation sources generally emit long-wave UV radiation between 310 and 400 nm. Printing form precursors sensitive to these particular UV sources use fluorinated elastomeric-based compounds (and initiators) that absorb between 310 to 400 nm.

As shown in FIG. 5, the stamp 5, which includes the support 16, is separated from the master 12 by peeling. The support 16 on the stamp 5 is sufficiently flexible in that the support and the stamp can withstand the bending necessary to separate from the master 12. The support 16 remains with the cured elastomeric layer 24 providing the stamp 5 with the dimensional stability necessary to reproduce micropatterns and microstructures associated with soft lithographic printing methods. The stamp 5 includes on a side opposite the support 16 a relief surface 26 having recessed portions 28 and raised portions 30 corresponding to the negative of the relief pattern 13 of the master 12. In one embodiment, the relief surface 26 has a difference in height between the raised portion 30 and the recessed portion 28, that is relief depth, of about 0.1 to 10 microns. In another embodiment the relief depth is between 0.3 to 5 microns. The relief surface of the stamp may include a layer of cured fluorinated elastomeric material as a floor (i.e., lowermost surface) to the recessed portions of the relief. In alternate embodiments (not shown) the lowermost surface of the recessed portions of the relief surface may be the support. Or, the lowermost surface of the recessed portions of the relief surface may be the adhesive layer or the thin metal layer. In some end use applications, the raised surface of the stamp provides the pattern for the electronic device or component.

The stamp with its elastomeric patterned relief surface is suitable for use in soft lithographic methods to generate micropatterns and microstructures. Soft lithographic methods include microcontact printing (μCP), replica molding (REM), embossing, micro transfer molding (μTM), micromolding in capillaries (MIMIC), solvent-assisted micromolding (SAMIM), and phase-shift photolithography.

It is also contemplated that the present printing form precursor could be used in other applications such as for micro lens arrays, light guides, optical switches, fresnel zone plates, binary elements, optical elements, filters, display materials, record media, microreactor chips, and antireflection coating components.

### EXAMPLES

Unless otherwise indicated, all percentages are by weight of the total composition.

Glossary

| | |
|---|---|
| BHT | Butylated hydroxytoluene |
| PFPE | Perfluoropolyether |
| FLK-D20 Diol | Perfluoropolyether diol (molecular weight of 2000) |
| FLK-D40 Diol | Perfluoropolyether diol (molecular weight of 4000) |
| E10-DA/CN4000 | PFPE diacrylate (molecular weight of1000) |
| PTFE | Polytetrafluoroethylene |
| THF | Tetrahydrofuran |
| UV | ultraviolet radiation |

### Example 1

The following example demonstrates the preparation of a stamp made of a photosensitive composition having a polyfluoropolyether (PFPE) and a fluorinated photoinitiator.

A polyfluoropolyether compound according to Formula 1A, D20-DA diacrylate, was prepared by the following procedure. A solution of FLK-D20 Diol purchased from Solvay Solexsis (Thorofare, N.J.) (10 gr, 0.005 mol, 1 eqv.) and BHT (1 wt % FLK-D20 0.001 gr) in anhydrous THF (100 ml) was allowed to stir in a 3-neck round bottom reaction flask (250 ml) equipped with a dropping funnel, thermometer, condenser and N₂ purge adapter. The reaction flask was cooled down to 0° C. using an ice-water bath. Triethylamine (1.948 gr, 0.0193 mol, 3.85 eqv.) was added dropwise to the solution of FLK-D20 Diol in THF over a 15 minute period. The reaction was maintained at 0° C. A second dropping funnel charged with acryloyl chloride (1.585 gr, 0.0185 mol, 3.5 eqv.) was added dropwise to the solution over a 60 min period. The temperature of the mixture was not allowed to exceed 5° C. A thick salt precipitated out upon addition of the acryloyl chloride. The mixture was allowed to warm up to 10-15° C. for 2 hours, then allowed to reach room temperature where the reaction stirred overnight under a N₂ atmosphere. The reaction mixture was poured into 500 ml of distilled water and stirred for 2 hrs. The D20-DA was extracted from the water solution with ethyl acetate or methylene chloride; providing about 83% conversion. Crude product was purified by running the solution through an alumina column to yield a clear, colorless oil. The structure of the prepared perfluoropolyether (pre-polymer) compound was according to Formula 1A, having acrylate end-groups (where X and X′ are H) and having a molecular weight of about 2000 based on a number average.

A fluorinated initiator was prepared according to the following reaction in the following procedure.

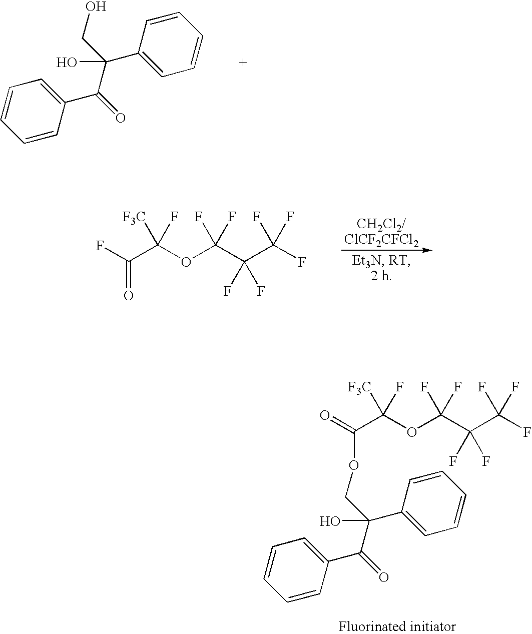

| | | Molar | Reaction | | | |
|---|---|---|---|---|---|---|
| | | Mass | Mass | | Volume | |
| Compound | Structure | (g) | (g) | Moles | (mL) | Equiv. |
| alpha- | C₁₅H₁₄O₃ | 242.27 | 20.00 | 0.083 | | 1.00 |
| hydroxymethyl- | | | | | | |
| benzoin | | | | | | |
| HFPO-dimer | C₆F₁₂O₂ | 332.044 | 32.89 | 0.099 | | 1.20 |
| acid fluoride | | | | | | |
| Methylene | | | | | 100 | |
| Chloride | | | | | | |
| Freon-113 | | | | | 60 | |
| Triethylamine | Et₃N | 101.19 | 8.35 | 0.083 | | 1.00 |
| Product | C₂₁H₁₃F₁₁O₅ | 554.307 | 45.76 | 0.083 | | |

### Procedure to Prepare the Fluorinated Photoinitiator:

To a 500 mL round bottom flask was added α-hydroxymethylbenzoin (20.14 g), triethylamine (Fluka, 8.40 g) and methylene chloride (100 mL). The mixture was magnetically stirred under positive nitrogen pressure at room temperature. To a separate flask was added HFPO dimer acid fluoride (32.98 g) and Freon-113 (CFCl₂CF₂Cl, Aldrich, 60 mL). The acid fluoride solution was added dropwise to the stirring α-hydroxymethylbenzoin solution at 4-5° C. over 30 minutes in order to control the exothermic reaction. The reaction pot stirred for 2.5 hrs at room temperature after the addition was complete.

The reaction was washed with 4×500 mL saturated NaCl solution. The organic layer was dried over MgSO₄ and filtered over a celite/methylene chloride pad. TLC analysis indicated a small amount of starting material remained in the crude product. The product was concentrated in vacuo and then dissolved in hexanes (100 mL). This solution was pre-absorbed onto silica gel and washed through a silica column using 90:10 hexanes:EtOAc eluent. The desired product was isolated as a light yellow oil which was a mixture of diastereomers (33 g, 72% yield).

The photosensitive composition was prepared by mixing 1 weight % of the carbon-based fluorinated initiator with the perfluoropolyether D20-DA diacrylate that were prepared previously. The mixture was stirred for 24 hours at room temperature.

A printing form precursor was prepared by pouring the liquid PFPE photosensitive composition onto a developed photoresist pattern on a 4 inch silicon wafer used as a master, forming a layer having a wet thickness of 25 micrometers (microns).

A support was prepared by applying a layer of a UV curable optically-clear adhesive, type NOA73, (purchased from Norland Products; Cranbury, N.J.) at a thickness of 5 microns onto a 5 mil (0.0127 cm) Melinex® 561 polyester film support by spin coating at 3000 rpm and then curing by exposure to ultraviolet radiation (350-400 nm) at 1.6 watts power (20 mWatt/cm²) for 90 seconds in a nitrogen environment.

The support was placed on the PFPE pre-polymer layer opposite the master (air-layer interface), such that the adhesive was in contact with the layer. The layer was exposed through the support using a 365 nm I-liner (OAI Mask Aligner, Model 200) for 600 seconds, to cure or polymerize the PFPE layer and form a stamp. The stamp was then peeled from the master and had a relief surface that corresponded to the pattern in the master. The relief surface of the stamp was characterized optically by an optical micrograph. The micrograph showed 10 micron dot and line features which were the negative image of the photoresist master. The stamp had excellent dot and line features since there were no or only very small defects. Haze was measured with a Hazegard Plus (from BYK Gardner) according to ASTM D1003. The haze of the plate was 0.21%.

### Example 2

The following example demonstrates the preparation of a stamp made of a polyfluoropolyether composition with a non-fluorinated photoinitiator.

The polyfluoropolyether compound, D20-DA diacrylate, was prepared as described in Example 1. The plate composition was prepared by mixing 1 weight % of a non-fluorinated photoinitiator, Darocur 4265, (from Ciba Specialty Chemicals, Basel, Switzerland) illustrated below with the D20-DA. Darocur 4265 is a 50/50 mixture of the two structures shown in (a) and (b). The mixture was stirred for 24 hours at room temperature.

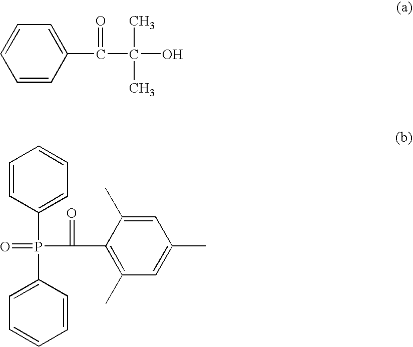

The non-fluorinated photoinitiator was immiscible in the PFPE pre-polymer compound, rendering an non-homogenized mixture. The non-homogenized mixture was then used to make PFPE stamp following the procedure described in Example 1.

The relief surface of the stamp was characterized by optical micrograph. The micrograph showed good 10 micron dot and line features and many bubbles. The bubbles were defects in some of the dot and line features. The immiscibility of the PFPE diacrylate pre-polymer compound and initiator led to many bubbles in the stamp. The haze of the stamp was measured as described in Example 1, and was 0.48%. The haze of the stamp having the non-fluorinated photoinitiator was considerably higher than haze of the counterpart stamp of Example 1 that was prepared with a fluorinated photoinitiator.

The stamp of Example 2 had higher haze due to the immiscibility of the PFPE (pre-polymer) compound and non-fluorinated photoinitiator. Higher haze influences exposure of the PFPE elastomeric layer such that the crosslinking density can be different locally which can then affect the dimensional stability of the stamp in a large area. Haziness also can limit effective and uniform curing of the PFPE layer in order to form the quality of the fine features necessary for electronic imprinting. Although the relief surface of the stamp of Example 2 had some bubbles, the stamp was not warped or distorted due to the presence of the support, and may be useful in some soft lithographic end-use applications.

### Examples 3 and 4

The following examples demonstrate the difference in dimensional stability of stamps prepared with and without a support.

Both stamps were prepared using a 4 inch (10.16 cm) Silicon (Si) wafer as a master since it provided a highly flat and uniform surface.

The stamp of Example 3 was prepared according to Example 1, except that the stamp did not include the Melinex® 561 polyester support. The layer was exposed (through the side opposite the master) in a nitrogen box for 10 min at the I-liner wavelength of 365 nm. The thickness of the cured stamp was about 1.5 mm. The layer cured to form a stamp without a support (i.e., freestanding stamp) but delaminated from the master during the curing process and was largely deformed.

The stamp of Example 4 was prepared according to Example 1, except that the stamp included a support. After the mixture was poured onto the master, a 5 mil Melinex® 561 polyester support having the adhesive layer as described in Example 1 was applied to the PFPE pre-polymer/air interface (i.e., a side of the layer opposite the master) prior to UV curing. The layer was exposed through the support in nitrogen box for 10 min at 365 nm wavelength through the support. The stamp was peeled from the Si wafer and had a relief surface that corresponded to the pattern on the master. The stamp did not deform during curing. After the stamp was repositioned onto the master by lamination, and relief areas on the stamp matched with corresponding pattern areas on the Si wafer showing that the stamp maintained its dimensional stability and did not deform throughout the lamination process.

### Examples 5 and 6

The following examples demonstrate the difference in surface roughness of stamps of PFPE prepared with and without a support.

Both stamps were prepared using a 4 inch (10.16 cm) Silicon (Si) wafer as a master since the wafer provided a highly flat and uniform surface adequate to evaluate the resulting surface roughness of the stamp.

A polyfluoropolyether compound according to Formula 1A, D40-DA was supplied by Sartomer and used as received. The polyfluoropolyether compound (pre-polymer) made had structure according to Formula 1A, having acrylate end groups (X and X′ were hydrogen), and the molecular weight was about 4000.

For Example 5, the stamp composition was prepared by mixing the D40-DA PFPE pre-polymer prepared above with 1 weight % of a photoinitiator, Darocur 1173 (from Ciba Specialty Chemicals, Basel, Switzerland). The structure of Darocur 1173 is as follows.

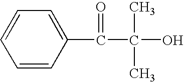

The mixture was stirred for 24 hours at ambient temperature. The homogenous mixture was then poured onto Si wafer to a 1.5 mm in thickness, but no support was applied to the layer of PFPE pre-polymer. The layer was exposed from a side of the layer opposite the master in nitrogen box for 10 min at the I-liner wavelength of 365 nm, to cure the layer and form the stamp. The thickness of the cured stamp was about 1.5 mm.

The surface roughness of the stamp was measured using Nanoscope IV Atomic Force Microscope (from Veeco Instrument) which provided AFM images and surface roughness calculations. The AFM images were acquired in Tapping Mode under ambient conditions. The surface of the stamp that had contacted the master was measured for roughness. The surface roughness of the stamp of Example 5 was very rough and had a root mean square roughness of 33 nm.

No deformation of the elastomeric layer or delamination of the layer from the master for the stamp of Example 5 was observed microscopically. However, the Applicants contemplate that the stamp of Example 5 had a high surface roughness because the support was not present to stabilize the stamp during curing, and that dimensional instability on a very small scale occurred.

The stamp of Example 6 was prepared the same as the stamp of Example 5 except that a 5 mil (12.7 cm) Melinex® 561 polyester film support that had the adhesive layer as described in Example 1 was applied to the layer of the PFPE (pre-polymer) compound prior to curing. The stamp was peeled from the Si wafer. The stamp of Example 6 had a smooth surface, and had a root means square surface roughness of 4.6 nm.

The surface roughness of the Example 6 stamp was significantly less rough than the surface roughness of the Example 5 stamp. The smooth surface of the stamp provides improved conformal contact and uniform printing of ink on a substrate in a printing process, compared to the stamp of Example 5 that has a relief surface that was rough.

### Example 7 and 8

The following Examples 7 and 8 demonstrate the difference in the sagging of the features of a stamp on the wafer substrate between PFPE elastomer having different molecular weights.

A perfluoropolyether compound, E10-DA was supplied by Sartomer as product type CN4000 and was used as received. The E10-DA has a structure according to Formula 1, wherein R and R′ are each an acrylate, E is a linear non-fluorinated hydrocarbon ether of (CH₂CH₂O)₁₋₂CH₂, and E′ is a linear hydrocarbon ether of (CF₂CH₂—O—(CH₂CH₂O)₁₋₂, and having a molecular weight of about 1000.

A Si wafer master was prepared with a pattern having gradually increasing line and width using SU-8 type 2, negative photoresist (from MICRO CHEM, Newton, Mass.). The SU-8 type 2 photoresist was diluted with Gamma Butyrolactone with weight ratio of 5/3 to make low-height line features. The diluted SU-8 type 2 was spun coated on Si wafer with 3000 rpm for 60 sec. The coated wafer was prebaked at 65° C. for 1 min and 95° C. for 1 min. The prebaked wafer was uv exposed for 7 sec using the Mask Aligner (described in Example 1) through a glass photomask having gradually increasing line and width pattern. The glass photomask was vacuum contacted on top of the prebaked wafer during the exposure. The exposed wafer was postbaked at 65° C. for 1 min and 95° C. for 1 min, and then was developed for 60 sec in SU-8 developer (from MICRO CHEM). The resulting line features have a height of 350 nm which was measured by profiler (KLA, Tencor P15).

For Example 7, the stamp composition was prepared by mixing the E10-DA PFPE pre-polymer with 1 weight % of a photoinitiator, Darocur 1173. The mixture was stirred for 24 hours at ambient temperature and filtered with 0.45 micron PTFE filter. The homogeneous mixture was poured onto the prepared Si wafer master with the pattern of photoresist.

An adhesive layer of NOA 73 was applied on a 5 mil MELINEX® 561 polyester film support by spin coating at 3000 rpm for 60 sec, and then cured by exposure to uv radiation for 90 sec in a nitrogen environment. The support was positioned on the PFPE layer so that the adhesive layer contacted the PFPE layer. The PFPE layer was cured by exposing through the support to UV for 10 min using the Mask Aligner, to form the stamp with the support. The stamp was peeled from the Si wafer master and had a relief surface that corresponded to the pattern on the master.

The stamp was placed on a flat Si wafer to observe sagging of line features under microscope. The sagging of features started from 50 micron line and spacing features. From this result, the aspect ratio (w/h) for sagging of this stamp was about 140. (50 micron (width)/350 nm (height)).

The modulus of elasticity of the stamp (elastomeric layer and support) was measured using a Hysitron Triboindenter equipped with a Berkovich diamond indenter (142 degree included angle). The modulus of elasticity of the stamp of Example 7 was 44 M Pa (mega Pascals; 106 Pascals). No plastic deformation was observed, so it is believed that the support did not influence the modulus, and that the measured modulus of elasticity is substantially that of the fluorinated elastomer-based layer of the stamp.

For Example 8, the stamp composition was prepared the same as the stamp composition of Example 6. The stamp of Example 8 was prepared the same as the stamp of Example 7 using the Si wafer master having the gradually increasing line and width pattern.

The stamp of Example 8 was placed on the flat Si wafer to observe sagging of line features under the microscope. The sagging of features started from 5 micron line and spacing features. From this result, the aspect ratio (5 micron (width)/350 nm (height)) for sagging of the stamp was about 14.

The modulus of elasticity of the stamp of Example 8 was measured to be 9 Mega Pascals.

Comparison of the stamps from Examples 7 and 8, showed that the stamp of Example 8, which was made of PFPE having a molecular weight of 4000, was not adequate for printing high aspect ratio features due to the sagging problem resulting from the low modulus of the stamp. The stamp of Example 7, which was made of PFPE having a molecular weight of 1000, had a higher modulus of elasticity and a higher aspect ratio and would be expected to print the fine features.

The stamp of Example 7 was used to print a silver ink (20 wt % nanoparticle silver ink in toluene) on a polyethylene terephthalate substrate (Mylar®). The stamp printed high resolution lines of 5 micron line width. If the stamp of Example 8 is used to print the silver ink, Applicants expect that the printed lines would not be as good as the lines printed by the stamp of Example 7. That is, the stamp of Example 8 is not capable of printing the high resolution lines of 5 micron line width. This is expected because the silver ink would not wet the Example 8 stamp surface well enough (due to low surface energy of the stamp), and sagging of the stamp would cause low resolution images by printing the recessed regions of the relief surface.

### Examples 9 and 10

The following examples demonstrate a printing form precursor having a support without a curable adhesive layer between the layer of the fluorinated compound and the flexible film.

For Example 9, the photosensitive composition was prepared and formed into a stamp with the support and the adhesive layer as described for Example 7. The PFPE elastomeric layer of the stamp with this support did not deform or warp when cured.

A strip of Highland 6200 tape was laminated onto at least a portion of the PFPE elastomeric layer side of the stamp, and quickly removed. The tape did not lift or delaminate the elastomeric layer from the adhesive coated support.

For Example 10, the photosensitive composition was prepared and formed into a stamp with a support as described for the stamp of Example 7, except that the Melinex support film did not include the UV curable NOA adhesive layer. A surface of the Melinex support film in contact with the PFPE layer was surface-treated to promote adhesion. The PFPE layer of the stamp with this support did not deform or warp when cured.

As was described for Example 9 a strip of Highland 6200 tape was laminated on PFPE side and quickly removed. The tape lifted or delaminated the elastomeric layer from the surface-treated support.

These results demonstrate that the support, regardless of the presence of the additional adhesive layer, provided dimensional stability to the cured fluorinated elastomeric layer of the stamp. But that the presence of the additional adhesive layer enhanced the adhesion of the fluorinated elastomeric layer to the support.

What is claimed is:

1. A printing form precursor for forming a relief structure comprising:
a layer of a composition comprising a fluorinated compound capable of polymerization by exposure to actinic radiation; and a support of a flexible film transparent to the actinic radiation adjacent the layer.

2. The printing form precursor of claim 1 wherein the fluorinated compound is a perfluoropolyether compound.

3. The printing form precursor of claim 1 wherein upon exposure to the actinic radiation, the layer has a modulus of elasticity of at least 10 mega Pascals.

4. The printing form precursor of claim 2 wherein the perfluoropolyether is according to Formula 1
R-E-CF₂—O—(CF₂—O—)ₙ(—CF₂—CF₂—O—)ₘ—CF₂-E′-R′ Formula 1
wherein n and m designate the number of randomly distributed perfluoromethyleneoxy and perfluoroethyleneoxy backbone repeating subunits, respectively, and wherein a ratio of m/n can be from 0.2/1 to 5/1; E and E′, which can be the same or different, are each an extending segment selected from the group consisting of linear alkyls of 1 to 10 carbon atoms, branched alkyls of 1 to 10 carbon atoms, linear hydrocarbon ethers of 1 to 10 carbon atoms, and branched hydrocarbon ethers of 1 to 10 carbon atoms; and, R and R′, which can be the same or different, are photoreactive segments selected from the group consisting of acrylates, methacrylates, allylics, and vinyl ethers.

5. The printing form precursor of claim 4 wherein n and m provide the compound of Formula 1 with a molecular weight of about 250 to about 4000.

6. The printing form precursor of claim 4 wherein the compound of Formula 1 has a molecular weight of about 250 to about 4000.

7. The printing form precursor of claim 2 wherein the perfluoropolyether is according to Formula 1A 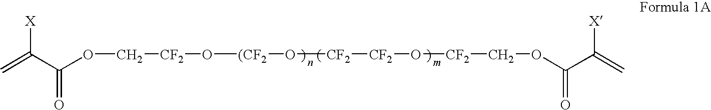
wherein n and m designate the number of randomly distributed perfluoromethyleneoxy and perfluoroethyleneoxy backbone repeating subunits, respectively, and wherein a ratio of m/n can be from 0.2/1 to 5/1, and X and X′ which can be the same or different, are selected from the group consisting of hydrogen and methyl.

8. The printing form precursor of claim 7 wherein the perfluoropolyether compound has a molecular weight between about 250 and 4000.

9. The printing form precursor of claim 7 wherein the perfluoropolyether compound has a molecular weight between about 900 and 2100.

10. The printing form precursor of claim 1 wherein the fluorinated compound is an elastomer.

11. The printing form precursor of claim 1 wherein the composition layer becomes elastomeric upon exposure to the actinic radiation.

12. The printing form precursor of claim 1 wherein the composition layer has a thickness between 5 and 50 micron.

13. The printing form precursor of claim 1 wherein the support is a polymeric film selected from the group consisting of cellulosic films, polyolefins, polycarbonates, polyimides, and polyethylenes.

14. The printing form precursor of claim 1 wherein the composition further comprises a photoinitiator.

15. The printing form precursor of claim 1 wherein the composition further comprises a fluorinated photoinitiator.

16. The printing form precursor of claim 1 wherein the composition further comprises a surfactant.

17. The printing form precursor of claim 1 wherein the composition further comprises an ethylenically unsaturated compound.

18. The printing form precursor of claim 1 wherein the composition further comprises a monomer selected from the group consisting of monofunctional acrylates, polyfunctional acrylates, monofunctional methacrylates, polyfunctional methacrylates, and combinations thereof.

19. The printing form precursor of claim 1 further comprising a layer of an adhesive between the support and the composition layer.

20. The printing form precursor of claim 1 further comprising a layer of metal between the support and the composition layer.

21. A method for making a stamp from a printing form precursor comprising:
(a) providing the printing form precursor, comprising a support of a flexible film transparent to actinic radiation and a layer of a composition of a fluorinated compound capable of polymerization by exposure to the actinic radiation, onto a master having a relief pattern such that the composition layer contacts the relief pattern;
(b) exposing the composition layer through the support to the actinic radiation, to polymerize the layer; and
(c) separating the polymerized layer from the master to form the stamp having a relief surface corresponding to the relief pattern of the master.

22. The method of claim 21 wherein the actinic radiation is ultraviolet radiation.

23. The method of claim 21 wherein the fluorinated compound is a perfluoropolyether compound.

24. A printing stamp prepared according to the method of claim 21.

25. A method for patterning a substrate comprising:
(A) preparing a stamp according to claim 21, wherein the relief surface of the stamp comprises raised portions and recessed portions;
(B) providing an ink on the relief surface of the stamp; and
(C) transferring the ink from the raised portions of the relief surface to the substrate.

26. A method for patterning a substrate comprising:
(A) preparing a stamp according to claim 21, wherein the relief surface of the stamp comprises raised portions and recessed portions;
(B) providing a layer of electronic material capable of curing by exposure to actinic radiation on the substrate;
(C) pressing the stamp onto the layer of electronic material;
(D) exposing the electronic material to actinic radiation to cure the electronic material; and
(E) separating the stamp from the cured electronic material on the substrate.
